(19) United States
(12) Patent Application Publication
(10) Pub. No.: US 2013/0001840 A1
(43) Pub. Date: Jan. 3, 2013

(54) ELASTOMER PRODUCT, IN PARTICULAR AN AIR SPRING HAVING A BELLOWS, HAVING AN ELECTRICAL COMPONENT

(76) Inventor: Siegfried Reck, Nienburg (DE)

(21) Appl. No.: 13/602,901

(22) Filed: Sep. 4, 2012

Related U.S. Application Data
(63) Continuation of application No. PCT/EP2011/053257, filed on Mar. 4, 2011.

(30) Foreign Application Priority Data
Apr. 8, 2010 (DE) 10 2010 016 359.7

(51) Int. Cl. H05K 1/16; B32B 37/14; F16F 9/05

(52) U.S. Cl. 267/122; 174/254; 156/60

(57) ABSTRACT

An elastomer product having an elastomer component, in particular an air spring having a bellows, wherein an electrical component is embedded in the elastomer component of the elastomer product, and the elastomer component including at least one electrically conductive path. The electrical component is located on a carrier material. The electrically conductive path is designed to be elastically flexible and connected to the carrier material and the carrier material is connected to the surrounding elastomer of the elastomer component in a firmly bonded manner.

### CROSS REFERENCE TO RELATED APPLICATIONS

This application is a continuation application of international patent application PCT/EP 2011/053257, filed Mar. 4, 2011, designating the United States and claiming priority from German application 10 2010 016 359.7, filed Apr. 8, 2010, and the entire content of both applications is incorporated herein by reference.

### FIELD OF THE INVENTION

The invention relates to an elastomer product having an elastomer component, in particular an air spring having a bellows, in the elastomer component of which an electrical component is embedded, which electrical component contains at least one electrical conductor track. The invention also relates to a method for manufacturing such an elastomer product. Here, and in the text which follows, the term “electrical component” is to be understood as meaning a component which contains electrical and/or electronic parts.

### BACKGROUND OF THE INVENTION

Elastomer products in whose elastomer component an electrical component is embodied have been known for a long time from the prior art. For example, U.S. Pat. No. 6,581,755 discloses a conveyor belt in whose cover layer an electrically conductive loop is embedded for monitoring purposes. The loop is sewn onto a carrier web which is embedded in the cover layer of the conveyor belt. DE 195 44 856 C1 discloses that, for monitoring purposes, transponders are provided in the cover layer of a conveyor belt, whose transponders are arranged, for the purpose of protecting them against mechanical loading, in a separate flat body which has a high degree of tensile strength and a large bending capability. The electrical components which are known from the specified documents are suitable for embedding in the cover layer of a conveyor belt, the cover layer is not extended very much during the manufacture and later use of the conveyor belt and is subject to only small dynamic loads. In addition, the cover layer of a conveyor belt has a large thickness so that the components in the cover layer are, on the one hand, well protected against mechanical loads and, on the other hand, cannot easily damage the cover layer. The components can also be used in other elastomer products in areas which are only slightly extended and are subject to only small dynamic loads.

However, it is to be noted that the components are not suitable for use in areas of the elastomer component of an elastomer product which are subject to severe extension and to large dynamic loads during use. This applies all the more if the elastomer component is sensitive owing to a small thickness. The components which are known from the specified documents are therefore, for example, not suitable to be arranged in the area of the bellows of an air spring which rolls on the rolling piston of the air spring since this area is sensitive owing to the small thickness and is subjected to large degrees of extension and to dynamic loads. Both the carrier fabric with the conductor loop known from U.S. Pat. No. 6,581,755 and the body with the transponder known from DE 195 44 856 C1 would become detached from the bellows when it is subjected to large dynamic loads. This would cause the air spring to be destroyed.

However, the insertion of an electrical component into the area of the elastomer component of an elastomer product which is subjected to a particularly high degree of extension and/or particularly large dynamic loads is of particular interest with respect to performing, in this loaded area, measurements of physical variables (such as, for example, of the temperature, of the pressure or of the dielectric constant) which permit conclusions to be drawn about the state and the service life of the elastomer component.

### SUMMARY OF THE INVENTION

The invention is based on the object of providing an elastomer product in whose elastomer component an electrical component is embedded, which electrical component can be arranged in any desired areas of the elastomer component, has a simple design, is not destroyed during use of the elastomer product and does not cause the elastomer product to be destroyed. The invention is also based on the object of providing a method for manufacturing such an elastomer product.

The object is achieved in that the electrical component is located on a carrier material and the electrical conductor track is of elastically extendable design and is connected to the carrier material, and in that the carrier material is connected in a materially joined fashion to the surrounded elastomer of the elastomer component.

An advantage of the embodiments of the present invention is the fact that the electrical or electronic component can be arranged in any desired area of the elastomer of the elastomer component because the carrier material connects in a materially joined fashion to the surrounding elastomer of the elastomer component. The carrier material of the electrical component therefore becomes an integral component of the elastomer and does not act in the elastomer component as a foreign body which could become detached from the elastomer during use of the elastomer product. The elastomer product is therefore not destroyed by the electrical component. The electrical component is prevented from being destroyed by virtue of the fact that the electrical conductor tracks are of elastically extendable design and can therefore follow the extensions of the elastomer during the manufacture or during use of the elastomer product. A further advantage of the embodiments of the invention is the fact that the electrical component can be pre-assembled on the carrier material and can be easily introduced into the elastomer component during manufacture of the elastomer product.

According to one embodiment of the invention, the carrier material is elastically extendable. An advantage of this embodiment is that the carrier material can follow the extension of the surrounding elastomer well. This additionally prevents the carrier material from becoming detached from the surrounding elastomer.

According to another embodiment of the invention, the carrier material is a thin film which is composed of a plastic with a low melting point. A thin film is to be understood here and below as meaning a film which is thinner than 1 mm and whose thickness is preferably between 20 μm and 200 μm. In addition, a plastic with a low melting point is to be understood here and below as meaning a plastic whose melting temperature is significantly lower than the vulcanization temperature at which the elastomer of the elastomer component is vulcanized.

The melting temperature of the plastic is preferably between 50° C. and 90° C. at a vulcanization temperature of approximately 200° C. The film may be composed, for example, of copolyamide or ethylene vinyl acetate. An advantage of this embodiment is that, owing to the low thickness and owing to the low melting temperature during the vulcanization of the elastomer, carrier material connects quickly and in an easily materially joined fashion to the surrounding elastomer and virtually “dissolves” in the surrounding elastomer. After the electrical component has been installed in the elastomer, virtually only the electrical conductor tracks of the component remain, which electrical conductor tracks do not act as a foreign body in the elastomer of the elastomer component owing to their small extent and their elastic extendability.

According to another embodiment of the invention, the carrier material is composed of the same elastomer as the elastomer component in which the carrier material is embedded. An advantage of this embodiment is that the carrier material has the same material properties as the surrounding elastomer so that during the vulcanization of the elastomer, the carrier material connects particularly well thereto and does not constitute a foreign body in the elastomer. A further advantage of the embodiment is that it is possible to dispense with embodying the carrier material in the form of a film with a low thickness, and the carrier material is therefore easy to handle and not sensitive when it is being worked into the elastomer. Another advantage of this embodiment is that the adhesiveness of the carrier material and the adhesiveness of the elastomer can be used to secure the electrical component in its position during the manufacture of the elastomer component.

According to yet another embodiment of the invention, the conductor track is connected to the carrier material in a punctiform pattern. The advantage of this embodiment is that the connection between the carrier material and the electrical conductor track is locally limited and therefore the connection cannot act, or can only act to a small degree, as a foreign body in the surrounding elastomer.

According to a further embodiment of the invention, the conductor track is connected to the carrier material by means of a textile connecting method or is bonded to the carrier material. If a textile connecting method is selected, the carrier material is preferably manufactured from a fabric. Sewing and stitching are possible as textile connecting methods. As an alternative, the conductor track can be woven into the carrier material. The advantage of this embodiment is that the specified connecting methods are easy to manufacture and can be embodied in a punctiform pattern.

According to another embodiment of the invention, the component contains a plurality of conductor tracks which are connected to an electrically conductive adhesive. The advantage of this embodiment is that the electrically conductive adhesive can be used, on the one hand, to connect the electrical conductor tracks and, on the other hand, to connect each individual electrical conductor track to the carrier material, therefore performing a double function.

According to yet another embodiment of the invention, a transponder is arranged on the carrier material, wherein the conductor tracks are electrically coupled to the transponder. In this context, the electrical conductor track can be formed as an antenna for coupling to an ultra high frequency transponder or as a conductor loop for an inductively coupled transponder. The advantage of this embodiment is that the electrical component can store, receive and transmit information using the transponder. Furthermore, by using the transponder it is possible to design the electrical component as a sensor with which, for example, the temperature in the elastomer can be measured.

According to a further embodiment in the invention, the electrical component is formed as a sensor with which the dielectric constant of the elastomer can be measured. The dielectric constant of the elastomer changes during the course of time as a function of the loads which act on the elastomer product. The advantage of this embodiment is therefore that after the dielectric constant has been measured it is possible to estimate which loads have acted on the elastomer product and what the state and the residual service life of the elastomer product are.

According to another embodiment of the invention, the electrical component is embodied as an LC oscillatory circuit. The advantage of this embodiment is that the LC oscillatory circuit can easily be excited externally, with the result that after the excitation the dielectric constant can be determined in a simple manner. This makes it possible to estimate the dielectric constant and the residual service life of the elastomer product during maintenance work of the elastomer product.

According to yet another embodiment of the invention, the electrical component is composed of two spiral-shaped electrical conductor tracks which are wound one in the other and are electrically connected to one another in a criss cross pattern (and therefore form an LC oscillatory circuit). The advantage of this embodiment is that an LC oscillatory circuit is formed on the carrier material, which LC oscillatory circuit has a simple design and is composed exclusively of electrically extendable conductor tracks which do not become detached from the elastomer and therefore do not lead to destruction of the elastomer product.

According to a further embodiment of the invention, the conductor tracks are each composed of an electric core around which a metallic conductor is wound in a helical shape. In this context, the metallic conductor is preferably composed of aluminum or stainless steel because these materials do not react chemically with the elastomer when they are introduced into the elastomer and therefore maintain their electrical conductivity. One advantage of this embodiment is that the conductor tracks have a high degree of extendability. Such conductor tracks are known, for example, from DE 102 42 785 A1.

### BRIEF DESCRIPTION OF THE DRAWINGS

The invention will now be described with reference to the drawings wherein:

FIG. 1a shows an elastomer product in the form of an air spring;

FIG. 1b shows in detail the encircled area in FIG. 1a;

FIG. 2 shows an electrical component having a transponder;

FIG. 3 shows an electrical component having a transponder;

FIG. 4 shows an electrical component in the form of an LC oscillatory circuit;

FIG. 5 shows an equivalent circuit diagram of the LC oscillatory circuit shown in FIG. 4; and,

FIG. 6 shows a detail of an electrical conductor track.

### DESCRIPTION OF THE PREFERRED EMBODIMENTS OF THE INVENTION

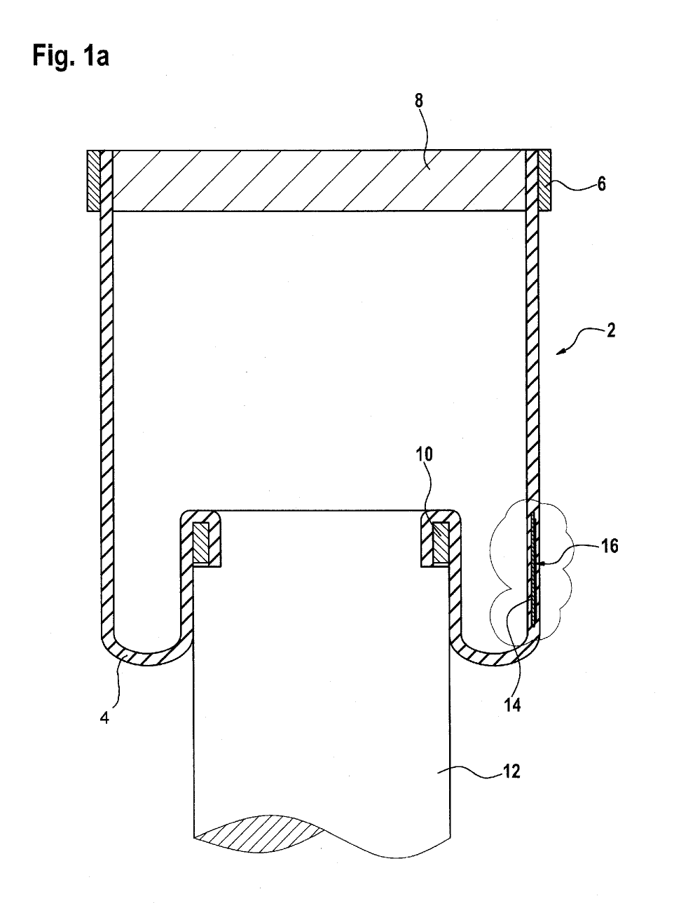

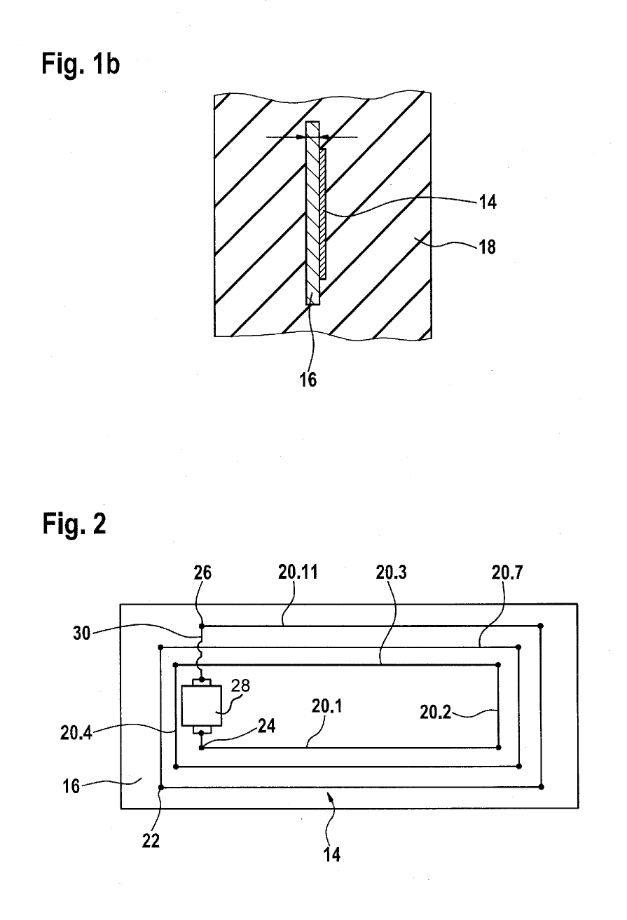

The invention will be explained with reference to FIG. 1a, on the basis of an elastomer product in the form of an air spring 2 for a motor vehicle having an elastomer component in the form of a bellows 4. However, the invention can be used in any desired elastomer products such as tires, hoses, transportation belts, drive belts et cetera. The bellows 4 is attached at its upper end to the cover 8 using a clamping ring 6, and at its lower end to the rolling piston 12 of the air spring by means of a clamping ring 10. An electrical component 14 is embedded in the bellows 4 in such a way that it is surrounded completely on all sides by the elastomer of the bellows 4. In this context, the electrical component is located in an area of the bellows which rolls on the rolling piston 12 and is therefore subject to severe mechanical loads. In order to introduce the electrical component 14 into the bellows 4 of the air spring, the electrical component 14 is arranged on a carrier material 16 and connected thereto. During the manufacture of the bellows 4, the carrier material 16 is embedded, with the electrical component 14 located thereon, in the elastomer of the bellows 4 before the vulcanization of the bellows 4. As a result of the vulcanization, the carrier material 16 connects in a materially joined fashion to the surrounding elastomer 18 of the bellows 4 (see also FIG. 1b which shows a detail from FIG. 1a).

FIG. 2 shows an electrical component 14 in a plan view. The electrical component 14 is arranged on a carrier material 16, and the electrical conductor tracks 20.1 to 20.11 are of elastically extendable design and connected in a punctiform pattern to the carrier material. This is done with the aid of an electrically conductive adhesive 22 which, on the one hand, connects the electrical conductor tracks 20.1 to 20.11 to one another in an electrically conductive fashion and, on the other hand, bonds the individual conductor tracks 20.1 to 20.11 onto the carrier material 16. Alternatively, it is possible to embody the carrier material as a fabric and to connect the electrical conductor tracks 20.1 to 20.11 to the carrier material 16 by means of a textile connecting method, for example by sewing or stitching. The electrical conductor tracks 20.1 to 20.11 can also be embodied as electrically conductive threads in the fabric.

The conductor tracks 20.1 to 20.11 form an electrically conductive coil whose ends 24 and 26 are connected in an electrically conductive fashion to a transponder 28. In this context, the end 26 is connected to the transponder via an electrical conductor track 30 which is made to extend over the electrical conductor tracks 20.3 and 20.7. In order to avoid an electrical short-circuit, all the conductor tracks can be provided with an electrically insulating coating toward the outside. Alternatively it is possible for the electrical conductor track 30 to be provided exclusively with an electrically insulating coating on the outside or for this electrically insulating coating to be limited to the areas in which the electrical conductor track 30 is in contact with the electrical conductor tracks 20.3 and 20.7.

The carrier material 16 for the electrical component 14 can be a film which has a low thickness and is composed of a plastic with a low melting point. In this case, the thickness (d) of the film (see also FIG. 1b) is less than 1 mm and is preferably between 20 μm and 200 μm. According to one alternative embodiment, the carrier material 16 for the electrical component 14 is composed of the same elastomer as the bellows 4 (see FIG. 1b).

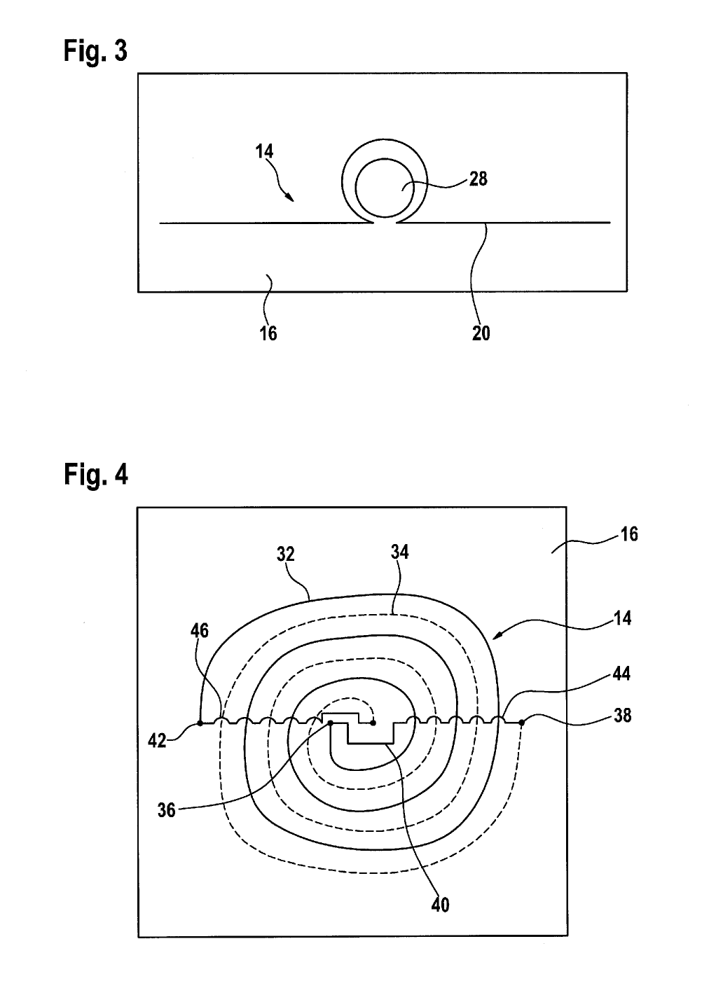

FIG. 3 shows an electrical component 14 which is arranged on a carrier material 16, in a plan view. The electrical component is composed of a conductor track 20 and a transponder 28. The electrical conductor track is formed as an antenna via which the transponder 28 can be supplied with electrical energy from an ultra-high-frequency electrical field. Reference is made to the statements relating to FIG. 2 with respect to the design of the electrical conductor tracks 20, of the carrier material 16 and of the connection of the electrical conductor track 20 with the carrier material 16.

FIG. 4 shows an electrical component 14 which is arranged on a carrier material 16, in a plan view. In particular, the electrical component is a sensor which is provided as an LC oscillatory circuit. For this purpose, the sensor has two spiral-shaped electrical conductor tracks 32 and 34, wherein the two spirals (32, 34) are wound one into the other. The spirals (32, 34) are electrically connected to one another in a criss cross pattern, that is, the inner end 36 of the spiral 32 is connected to the outer end 38 of the spiral 34, and the inner end 40 of the spiral 34 is connected to the outer end 42 of the spiral 32. The specified connections are made via electrical conductor tracks 44 and 46. The two spirals (32, 34) therefore each form an electrical coil and a capacitor between whose “capacitor plates” the elastomer 18 is located. The electrical component 14 is therefore embodied as a sensor with which the dielectric constant of the elastomer 18 can be measured (see also FIG. 1b). Reference is made to the description of FIG. 2 with respect to the attachment of the electrical conductor tracks 32, 34, 44 and 46 to the carrier material 16 and with respect to the embodiment of the carrier material 16.

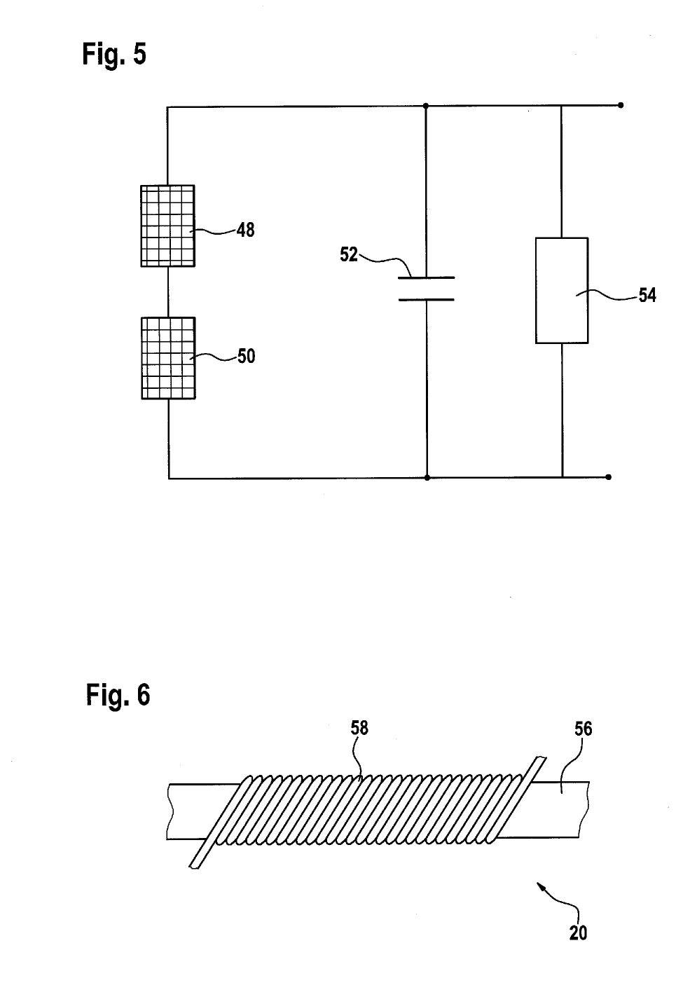

FIG. 5 shows the equivalent circuit diagram of the spirals (32, 34) which are wound one in the other and are shown in FIG. 4. The two spirals (32, 34) can be represented as two coils (48, 50) which are connected in series, and in parallel with which a capacitor 52 and a resistor 54 are connected. The LC oscillatory circuit shown in FIG. 5 can be coupled inductively to a second excited LC oscillatory circuit from the outside. The oscillatory circuit which is shown in FIG. 5 is then excited to undergo forced oscillations. Resonance occurs between the two oscillatory circuits if the oscillatory circuit shown in FIG. 5 is excited at a frequency which corresponds to the natural frequency ω₀ of the oscillatory circuit shown, wherein ω₀=1/(LC^{1/2}) (here L is the sum of the inductances of the coils 48 and 50 and C is the capacitance of the capacitor 52). The damping constant 5 can in turn be determined from the decay of the electrical oscillation or the amplitude of the current, wherein: δ=R/2L (here, R is the value of ohmic resistance 54). With the natural frequency ω₀ determined in this way and the damping constant δ of the oscillatory circuit which is shown in FIG. 5 it is finally possible to determine the complex dielectric constant. This changes in the course of time and permits conclusions to be drawn about the state and the residual service life of the elastomer 18, by which the electrical component 14 is surrounded (see FIG. 1b).

FIG. 6 shows an electrical conductor track 20 in a schematic illustration. The electrical conductor 20 is composed of an elastic core 56 which is surrounded by a metallic conductor 58 in the form of a helix. The metallic conductor can be provided on the outside with an electrically insulating layer if this is necessary to avoid an electrical short-circuit. All the electrical conductor tracks which have been mentioned in relation to FIGS. 1 to 5 can be constructed in the way shown in FIG. 6.

It is understood that the foregoing description is that of the preferred embodiments of the invention and that various changes and modifications may be made thereto without departing from the spirit and scope of the invention as defined in the appended claims.

### LIST OF REFERENCE NUMERALS (PART OF THE DESCRIPTION)

2 Air spring
4 Bellows
6 Clamping ring
8 Cover
10 Clamping ring
12 Rolling piston
14 Electrical component
16 Carrier material
18 Elastomer
20 Electrical conductor track
22 Adhesive
24 End
26 End
28 Transponder
30 Electrical conductor track
32 Electrical conductor track
34 Electrical conductor track
36 Inner end
38 Outer end
40 Inner end
42 Outer end
44 Electrical conductor track
46 Electrical conductor track
48 Coil
50 Coil
52 Capacitor
54 Resistor
56 Core
58 Conductor

What is claimed is:

1. An elastomer product comprising:
an elastomer component;
an electrical component embedded in the elastomer component;
the electrical component having an elastically extendable conductor track;
a carrier material;
the electrical component being disposed on the carrier material and the elastically extendable conductor track being connected to the carrier material; and,
the carrier material being materially joined to surrounding elastomer of the elastomer component.

2. The elastomer product of claim 1, wherein the carrier material is elastically extendable.

3. The elastomer product of claim 1, wherein the carrier material is a thin film which is composed of a plastic with a low melting point.

4. The elastomer product of claim 1, wherein the carrier material is composed of the same elastomer as the elastomer component in which the carrier material is embedded.

5. The elastomer product of claim 1, wherein the conductor track is connected to the carrier material in a punctiform pattern.

6. The elastomer product of claim 1, wherein the conductor track is connected to the carrier material by means of a textile connecting method or is bonded to the carrier material.

7. The elastomer product of claim 1, wherein the electrical component contains a plurality of conductor tracks which are connected to an electrically conductive adhesive.

8. The elastomer product of claim 1, wherein a transponder is arranged on the carrier material and the conductor tracks are electrically connected to the transponder.

9. The elastomer product of claim 1, wherein the electrical component is a sensor with which the dielectric constant of the elastomer of the elastomer component can be measured.

10. The elastomer product of claim 9, wherein the electrical component is an LC oscillatory circuit.

11. The elastomer product of claim 10, wherein the electrical component is composed of two spiral-shaped electrical conductor tracks which are wound one in the other and are electrically connected to one another in a criss cross pattern.

12. The elastomer product of claim 1, wherein the conductor tracks are each composed of an elastic core around which a metallic conductor is wound in a helical shape.

13. A method for manufacturing an elastomer product, the method comprising:
providing an electrical component including at least one electrical conductor track on a carrier material;
wherein the electrical conductor track is elastically extendable and is connected to the carrier material;
embedding the electrical component in an elastomer component before a vulcanization of the elastomer component; and
vulcanizing the elastomer component, whereby the carrier component is materially joined to surrounding elastomer of the elastomer component.

14. The elastomer product of claim 1, being an air spring including a bellows.

15. The method of claim 13, wherein the elastomer product is an air spring including a bellows.

16. An air spring comprising:
a cover;
a roll-off piston;
an elastomer flexible member connected between said cover and said roll-off piston;
an electrical component embedded in said elastomer flexible member;
said electrical component having an electric conductor track configured to be elastically extendible;
a carrier material;
said electrical component being disposed on said carrier material with said electrical conductor track being connected to said carrier material; and,
said carrier material being materially joined to the elastomer of said elastomer flexible member.
